(19) United States
(12) Patent Application Publication
(10) Pub. No.: US 2008/0150059 A1
(43) Pub. Date: Jun. 26, 2008

(54) Image Sensor and Method for Manufacturing the Same

(76) Inventor: Young Je Yun, Ansan-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/963,276

(22) Filed: Dec. 21, 2007

(30) Foreign Application Priority Data
Dec. 22, 2006 (KR) 10-2006-0132348

(51) Int. Cl. H01L 31/18; H01L 31/0232

(52) U.S. Cl. 257/432; 438/70; 257/E31.127

(57) ABSTRACT

An image sensor and a manufacturing method thereof are provided. An insulating layer structure can be formed on a photodiode region and can include a trench. A color filter structure can be formed on the insulating layer structure having color filters corresponding to photodiodes in the photodiode region. The upper surfaces of the color filters can be about even with each other.

### CROSS-REFERENCE TO RELATED APPLICATION

The present application claims the benefit under 35 U.S.C. §119 of Korean Patent Application No. 10-2006-0132348, filed Dec. 22, 2006, which is hereby incorporated by reference in its entirety.

### BACKGROUND

Image sensors are semiconductor devices that convert optical images into electrical signals and can be classified as charge coupled devices (CCD) or complimentary metal oxide semiconductor (CMOS) image sensors.

In a typical related art method for manufacturing an image sensor, transistors and a photodiode electrically connected to the transistors are formed on a semiconductor substrate. An insulating layer structure and an interconnection are formed on the transistors and the photodiode, and red, green, and blue color filters are formed on the insulating layer structure.

According to typical related art methods for manufacturing an image sensor, because the color filters have different thicknesses, a photoresist material is coated on an upper surface of the color filters to form a planar layer. Then, another photoresist film is coated on the upper surface of the planar layer, and a reflow process is performed to form a microlens to provide light concentrated on the photodiode. However, the planar layer covering the color filters can cause light loss. In other words, as the thickness of the planar layer increases, the sensitivity of an optical signal is degraded, such that the performance of the image sensor can also be degraded.

In addition, according to related art methods for manufacturing an image sensor, the planar layer can inhibit the microlens from being precisely focused on a pixel area. Accordingly, in order to compensate for a focus distance due to the thickness of the planar layer, the microlens is often formed to be thinner. However, this can reduce a process margin of the image sensor.

Furthermore, a coating strip pattern can be formed in the process of forming the microlens due to the difference in thickness between a pixel area formed with both the color filters and the planar layer and a scribe line having no color filters or planar layer.

Thus, there exists a need in the art for an improved image sensor and manufacturing method thereof.

### BRIEF SUMMARY

Embodiments of the present invention provide an image sensor and a manufacturing thereof capable of forming color filters having upper surfaces that are even with each other.

In an embodiment, an image sensor can include a photodiode region, an insulating layer structure including a trench on the photodiode region, and a color filter structure on the insulating layer structure. The color filter structure can include a first color filter, a second color filter, and a third color filter. The third color filter can be thicker than the first color filter, and the upper surface of the first color filter can be about even with the upper surfaces of the second color filter and the third color filter.

In an embodiment, a method for manufacturing an image sensor can include: forming a photodiode region on a semiconductor substrate; forming an insulating layer structure including a trench on the photodiode region; forming a first color filter by coating and patterning a first color filter material on the upper surface of the insulating layer structure; forming a second color filter by coating and patterning a second color filter material on the upper surface of the insulating layer structure; and forming a third color filter by coating and patterning a third color filter material on the upper surface of the insulating layer structure, wherein the third color filter is thicker than the first color filter, and the upper surface of the first color filter is about even with the upper surfaces of the second color filter and the third color filter.

### BRIEF DESCRIPTION OF THE DRAWINGS

FIG. 1 is a cross-sectional view showing an image sensor according to an embodiment of the present invention.

FIG. 2 is a plan view showing a photodiode region shown in FIG. 1.

FIGS. 3 to 8 are cross-sectional views showing a method for manufacturing an image sensor according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

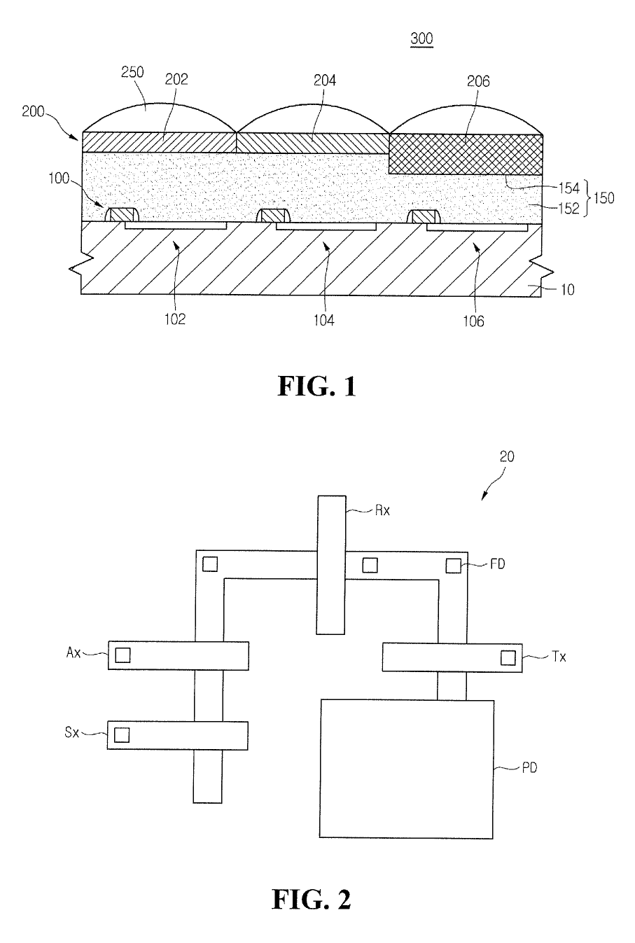

FIG. 1 shows an image sensor 300 according to an embodiment of the present invention, and FIG. 2 is a plan view showing a photodiode region shown in FIG. 1.

Referring to FIG. 1, the image sensor 300 according to an embodiment can include photodiode pixel regions 100, an insulating layer structure 150, a color filter structure 200, and microlenses 250. The photodiode pixel regions 100 can be formed in a pixel area of a semiconductor substrate 10 to generate an electrical signal by incident light. The photodiode pixel regions 100 can include any suitable number of photodiodes. In an embodiment, the photodiode pixel regions 100 can include a first pixel region 102, a second pixel region 104, and a third pixel region 106.

Referring to FIG. 2, each photodiode pixel region 20 of the photodiode pixel regions 100 (for example, the first pixel region 102, the second pixel region 104, and the third pixel region 106) can include a photodiode PD which can detect light, a transfer transistor Tx, a reset transistor Rx, a select transistor Sx, and an access transistor Ax. A drain of the transfer transistor Tx can serve as a floating diffusion FD region.

Referring again to FIG. 1, the insulating layer structure 150 can include an insulating layer 152 to insulate multi-layer interconnections (not shown) from each other by covering an upper portion of the semiconductor substrate 10 including the photodiode pixel regions (for example, the first pixel region 102, the second pixel region 104, and the third pixel region 106) and a trench 154 formed with a predetermined depth in an upper portion of the insulating layer 152 corresponding to a photodiode (for example, the third pixel region 106). The depth of the trench 154 can be, for example, about 300 nm to about 500 nm.

The color filter structure 200 can be formed on the upper surface of the insulating layer structure 150 to transmit light of specific colors. The color filter structure 200 can include a blue color filter 202, a green color filter 204, and a red color filter 206. In an embodiment, the blue color filter 202 can be formed on the upper surface of the insulating layer 152 corresponding to the first pixel region 102, the green color filter 204 can be formed on the upper surface of the insulating layer 152 corresponding to the second pixel region 104, and the red color filter 206 can be formed in the trench 154 of the insulating layer structure 150 corresponding to the third pixel region 106.

In an embodiment, the thickness of the blue color filter 202 can be approximately equal to the thickness of the green color filter 204 while the red color filter 206 can be thicker than the blue color filter 202 and the green color filter 204. The thickness of the red color filter 206 can be larger than that of the blue color filter 202 and the green color filter 204 by the depth of the trench 154. Thus, although the red color filter 206 is thicker than the blue color filter 202 and the green color filter 204, the upper surface of the red color filter 206 can be approximately even with the upper surface of the blue color filter 202 and the upper surface of the green color filter.

In an embodiment, in order to inhibit colors from being mixed with each other, which can sometimes occur when the green color filter 204 transmits not only the light having the green wavelength band but also the light having wavelengths similar to the blue wavelength, the green color filter 204 can be slightly thicker than the blue color filter 202. In order to form the color filter structure 200 with a uniform upper surface while forming the green color filter 204 slightly thicker than the blue color filter 202, a second trench having a depth corresponding to the difference in thickness between the green color filter 204 and the blue color filter 202 can be formed in a portion of the insulating layer 152 corresponding to the green color filter 204.

The microlenses 250 condense light to the photodiode pixel regions 100, and can be formed in a partially spherical shape on the upper surface of the color filter structure 200.

According to embodiments of the present invention the upper surface of the color filter structure 200 can be uniform and the microlens 250 can be formed directly on the color filter structure 200 without forming a planar layer.

Therefore, since a planar layer is not present between the color filter structure 200 and the microlens 250, light loss can be reduced while light is being transferred to the photodiode pixel region 100. Also, the microlens 250 can be focused more precisely on the photodiode PD, such that the microlens 250 can be easily formed. In addition, since a step difference between a scribe line and a pixel area formed with photodiode regions is only slightly generated, the occurrence of coating stripes can be inhibited during the coating of a photoresist material used to form the microlens 250.

In addition, color mixture phenomenon can be inhibited since the blue color filter 202, the green color filter 204, and the red color filter 206 can have varying thicknesses while the upper surface of the color filter structure 200 can be approximately uniform.

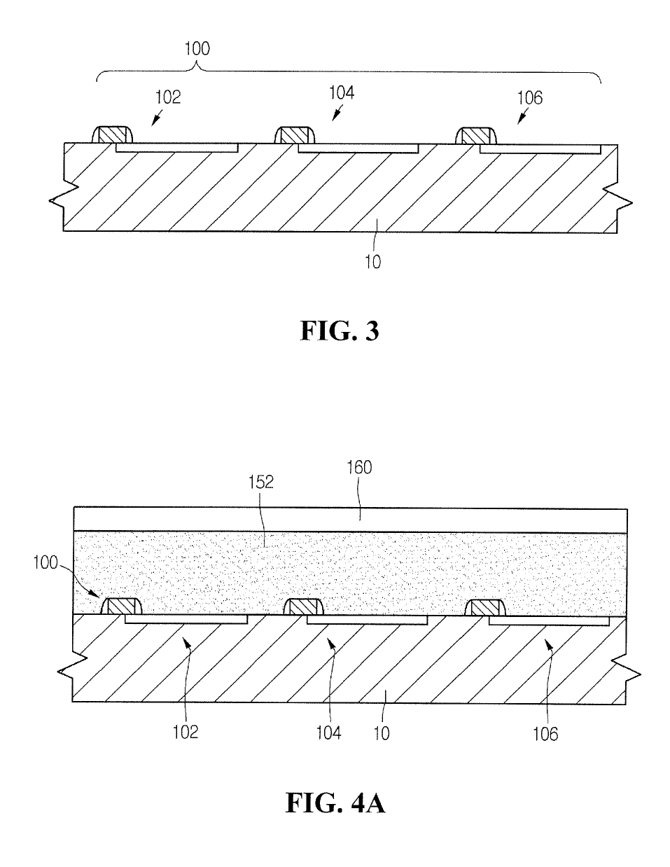

FIGS. 3 to 8 show a method for manufacturing an image sensor 300 according to an embodiment of the present invention.

FIG. 3 is a cross-sectional view showing photodiode pixel regions 100 of an image sensor according to an embodiment of the present invention.

Referring to FIG. 3, in the photodiode pixel regions 100 including the first pixel region 102, the second pixel region 104, and the third pixel region 106) can be formed on the semiconductor substrate 10. Although FIG. 3 shows the first pixel region 102, the second pixel region 104, and the third pixel region 106, the photodiode pixel regions 100 can include any suitable number of pixel regions as desired to provide a particular resolution.

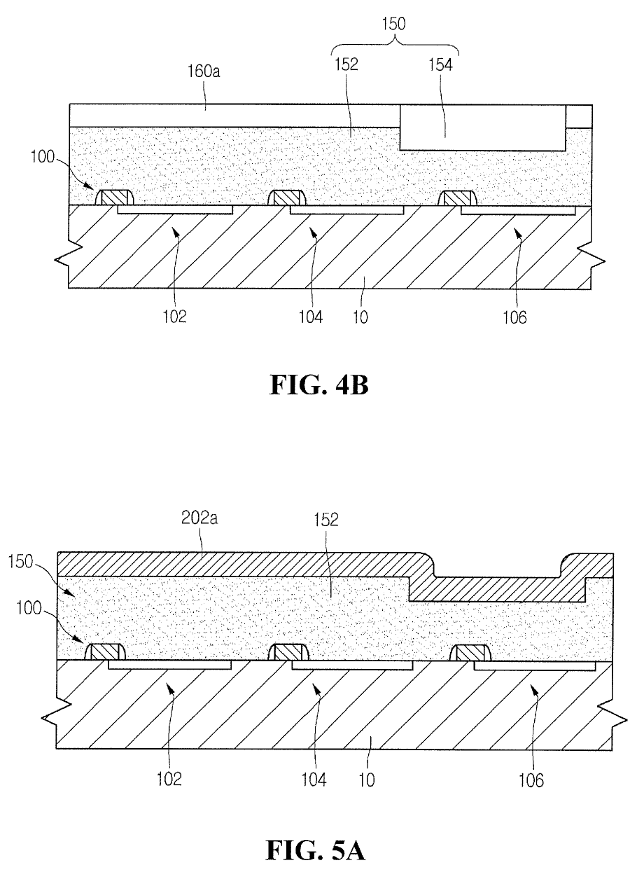

Referring to FIG. 4A, after forming the photodiode pixel regions 100 on the semiconductor substrate 10, an insulating layer 152 can be formed on the semiconductor substrate 10 over the pixel regions 100.

Then, a photoresist film 160 can be coated on the upper surface of the insulating layer 152. The photoresist film 160 can include, for example, a positive type photoresist material in which cross-links are disconnected in portions exposed to the light.

Referring to FIG. 4B, after the photoresist film 160 is coated on the insulating layer, the photoresist film 160 can be exposed by using an exposure mask such that a portion of the photoresist film 160 corresponding to the third pixel region 106 is exposed to light. Then, the photoresist film 160 can be patterned into a first photoresist pattern 160a by etching the photoresist film 160. When the photoresist film 160 is etched, only a portion of the photoresist film 160, in which the cross-link is disconnected through the reaction with light, that is, only the portion of the photoresist film 160 corresponding to the third pixel region 106 is removed.

Then, the insulating layer 152 can be etched through reactive ion etching (RIE) by using the first photoresist pattern 160a as an etch mask. By etching a portion of the insulating layer 152 corresponding to the third pixel region 106, a trench 154 having a predetermined depth can be formed. For example, the depth of the trench 154 can be about 300 nm to about 500 nm.

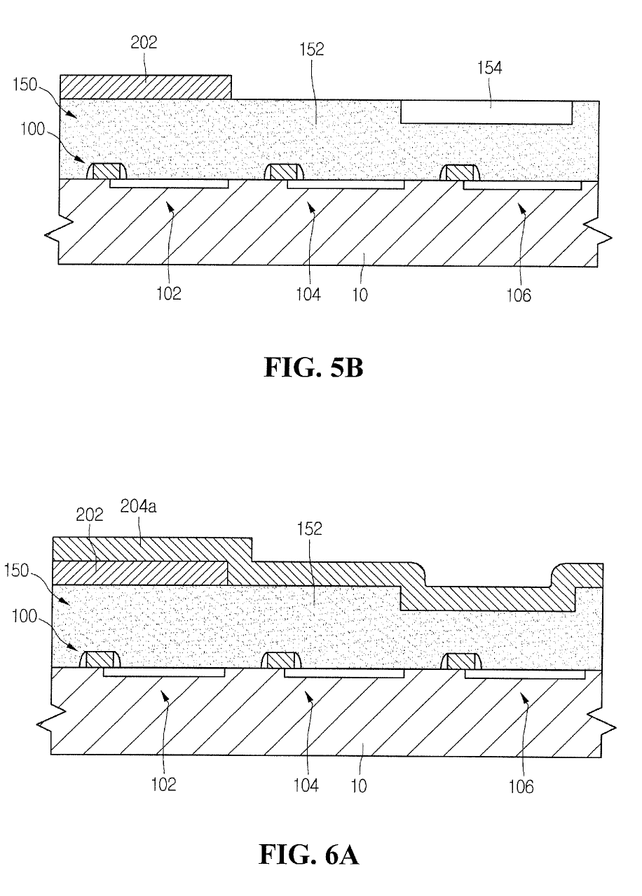

Referring to FIGS. 5A and 5B, after forming the insulating layer structure 150, the blue color filter 202 can be formed on the insulating layer structure 150.

In order to form the blue color filter 202, a blue color filter material can be coated over the entire surface of the insulating layer structure 150, thereby forming a blue color filter layer 202a. The blue color filter material can include, for example, a blue pigment and/or a dye and a photoresist material. In an embodiment, the photoresist material can be a negative type photoresist material, in which cross-links are formed in portions exposed to light.

Then, the blue color filter layer 202a can be patterned through a photo process including a lithography process and a development process to form the blue color filter 202 on the insulating layer structure 150 corresponding to the first pixel region 102.

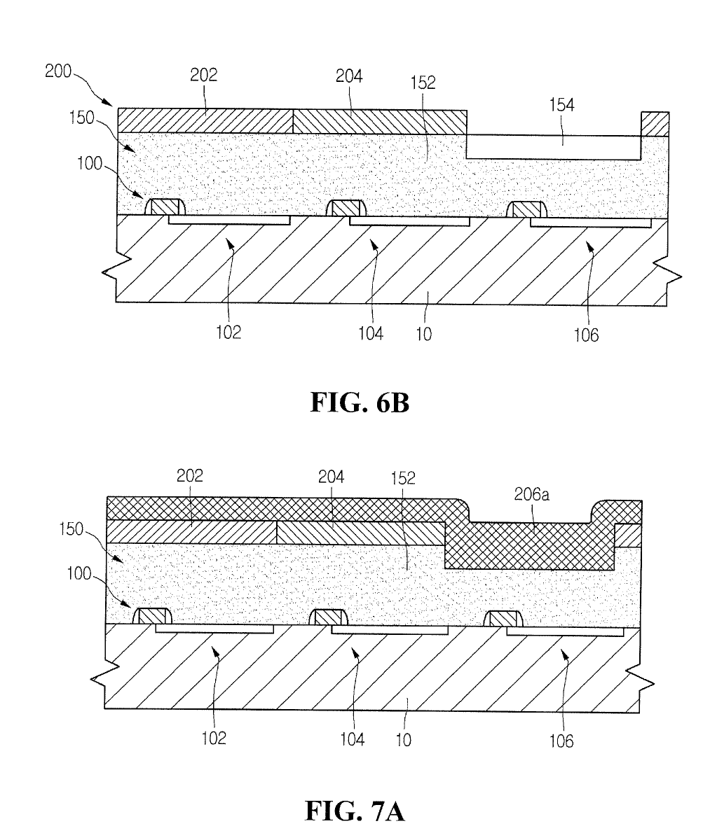

Referring to FIGS. 6A and 6B, the green color filter 204 can be formed on the insulating layer structure 150.

In order to form the green color filter 204, a green color filter material can be coated over the entire surface of the insulating layer structure 150, thereby forming a green color filter layer 204a. The green color filter material can include, for example, a green pigment and/or a dye and a photoresist material. In an embodiment, the photoresist material can be a negative type photoresist material in which cross-links are formed at portions exposed to light.

Then, the green color filter layer 204a can be patterned through a photo process including a lithography process and a development process to form the green color filter 204 on the insulating layer structure 150 corresponding to the second pixel region 104.

In one embodiment, the thickness of the green color filter 204 is approximately equal to the thickness of the blue color filter 202.

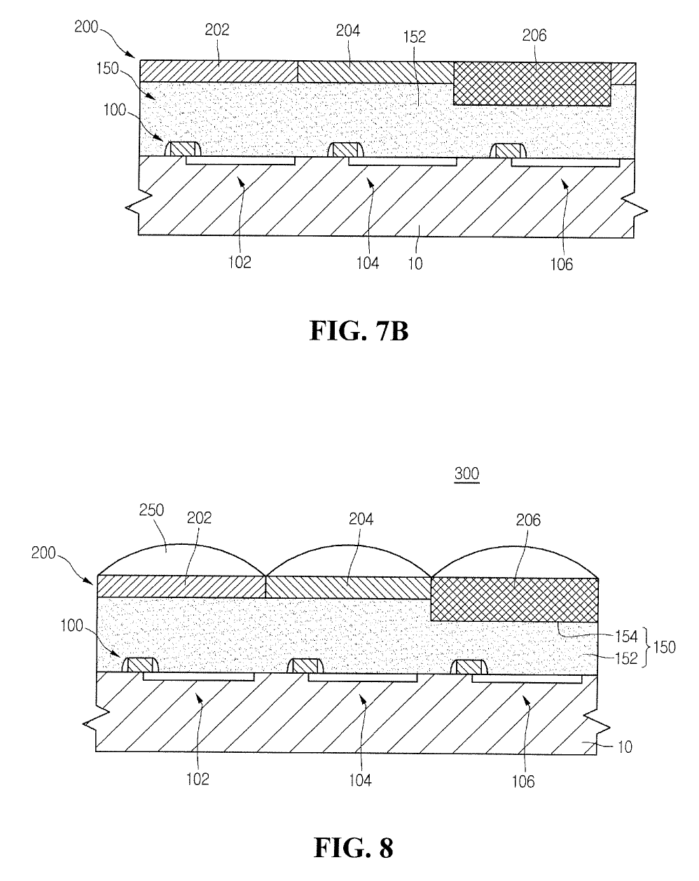

Referring to FIGS. 7A and 7B, the red color filter 206 can be formed on the insulating layer structure 150.

In order to form the red color filter 206, a red color filter material can be coated over the entire surface of the insulating layer structure 150, thereby forming a red color filter layer 206a. The red color filter material can include, for example, a red pigment and/or a dye and a photoresist material. In an embodiment, the photoresist material can be a negative type photoresist material, in which cross-links are formed at portions exposed to light.

Then, the red color filter layer 206a can be exposed by using an exposure mask processed such that a portion of the red color filter layer 206a over the trench 154 can be exposed to light. The red color filter layer 206a can be patterned through a process of developing the red color filter layer 206a to form the red color filter 206 in the trench 154. The red color filter 206 can be formed thicker than the blue color filter 202 and the green color filter 204.

The exposure process of the red color filter layer 206a can be performed by using the same exposure mask as that used to expose the photoresist film 160 coated on the upper surface of the insulating layer 152 in order to form the trench 154. If the red color filter layer 206a is patterned through the development process, only a portion of the red color filter layer 206a which has reacted with light to form a cross-link remains instead of being removed. That is, only a portion of the red color filter layer 206a over the trench 154 remains so that the red color filter 206 can be formed.

In an embodiment, the thickness of the red color filter 206 can be thicker than that of the blue color filter 202 and the green color filter 204 by the depth of the trench 154. Thus, referring to FIG. 7B, although the red color filter 206 can be thicker than the blue color filter 202 and the green color filter 204, the upper surfaces of the blue color filter 202, the green color filter 204, and the red color filter 206 are approximately even with each other due to the trench 154.

Then, referring to FIG. 8, after forming the red color filter 206 in the trench 154, a photoresist material can be directly coated on the upper surface of the blue color filter 202, the green color filter 204, and the red color filter 206, and then the resultant structure can be subject to a reflow process to form the microlens 250. Thus, no planar layer is needed to be formed on the upper surface of the blue color filter 202, the green color filter 204, and the red color filter 206.

According to an embodiment of the present invention, the thickness of the blue color filter 202 can be approximately equal to the thickness of the green color filter 204, and the red color filter 206 can be thicker than the blue color filter 202 and the green color filter 204 by the depth of the trench 154. Thus, the upper surfaces of the blue color filter 202, the green color filter 204, and the red color filter 206 can be about even with each other.

In another embodiment, in order to inhibit colors from being mixed with each other, which can sometimes occur when the green color filter 204 transmits light having wavelengths similar to the blue wavelength band, the green color filter 204 can be slightly thicker than the blue color filter 202. In order to form the color filter stricture 200 having a uniform upper surface while forming the green color filter 204 slightly thicker than the blue color filter 202, a trench having a depth corresponding to the difference in thickness between the green color filter 204 and the blue color filter 202 can be formed in a portion of the insulating layer 152 corresponding to the second pixel region 104. The trench 154 for the red color filter 204 can still be formed in a portion of the insulating layer 152 corresponding to the third pixel region 104. In such an embodiment, a second photoresist film can be used before or after patterning and developing the first photoresist film 160 and etching the insulating layer 152 to form the trench 154.

In embodiments of the present invention, the upper surface of the color filter structure can be uniform, so that the microlens can be directly formed on the top surface of the color filter structure without forming a planar layer. Accordingly, the manufacturing process of the image sensor can be simplified.

In addition, since a planar layer is not present between the color filter structure and the microlens, light loss can be reduced while light is being transferred to the photodiode region, and the microlens can be used to focus light on the photodiode more precisely. This can improve the performance of the image sensor and allow the microlens to be easily formed.

Furthermore, since a step difference between the scribe line and the pixel area formed with the photodiode regions can be thin, the occurrence of coating stripes can be minimized when the photoresist material is coated while forming the microlens. Accordingly, the occurrence of bending and discolor phenomena can be reduced.

Moreover, in an embodiment since the upper surface of the color filter structure is uniform, and the red and green color filters are thicker than the blue color filter, the color mixture phenomenon can be inhibited from occurring.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor, comprising:
a semiconductor substrate;
a first photodiode in a first pixel area, a second photodiode in a second pixel area, and a third photodiode in a third pixel area on the semiconductor substrate;
an insulating layer structure on the semiconductor substrate, wherein the insulating layer structure comprises a trench over the third pixel area; and
a color filter structure on the insulating layer structure, the color filter structure comprising a first color filter corresponding to the first pixel area, a second color filter corresponding to the second pixel area, and a third color filter corresponding to the third pixel area;
wherein the third color filter is provided on the trench.

2. The image sensor according to claim 1, further comprising a microlens on the color filter structure.

3. The image sensor according to claim 1, wherein the trench has a thickness of about 400 nm.

4. The image sensor according to claim 1, wherein the third color filter is thicker than the first color filter; and wherein an upper surface of the first color filter is about even with an upper surface of the second color filter and an upper surface of the third color filter.

5. The image sensor according to claim 1, wherein a thickness of the first color filter is approximately equal to a thickness of the second color filter.

6. The image sensor according to claim 1, wherein the insulating layer structure further comprises:
a second trench over the second pixel area, wherein the second color filter is provided on the second trench.

7. The image sensor according to claim 6, wherein the second color filter is thicker than the first color filter, and wherein the third color filter is thicker than the second color filter.

8. The image sensor according to claim 7, wherein an upper surface of the first color filter is about even with an upper surface of the second color filter and an upper surface of the third color filter.

9. The image sensor according to claim 1, wherein the first color filter is a blue color filter, the second color filter is a green color filter, and the third color filter is a red color filter.

10. A method for manufacturing an image sensor, comprising:
forming photodiode regions including a first photodiode, a second photodiode, and a third photodiode on a semiconductor substrate;
forming an insulating layer structure including a trench formed over the third photodiode;
forming a first color filter over the first photodiode on an upper surface of the insulating layer structure;
forming a second color filter over the second photodiode on the upper surface of the insulating layer structure; and
forming a third color filter over the third photodiode in the trench of the insulating layer structure.

11. The method according to claim 10, wherein forming the insulating layer structure comprises:
depositing a photoresist material on an insulating layer;
exposing and developing the photoresist film to form a photoresist pattern; and
etching the insulating layer using the photoresist pattern as an etch mask to form the trench;
wherein an exposure mask used to expose the photoresist film is identical to an exposure mask used to expose a material used to form the third color filter.

12. The method according to claim 11, wherein the photoresist film is a positive type photoresist material, and the material used to form the third color filter material is a negative type photoresist material.

13. The method according to claim 10, wherein forming the insulating layer structure comprises etching an insulating layer through reactive ion etching to form the trench.

14. The method according to claim 10, wherein the trench has a depth of about 400 nm.

15. The method according to claim 10, wherein a thickness of the second color filter is approximately equal to a thickness of the first color filter; and wherein the third color filter is thicker than the first color filter; and wherein an upper surface of the first color filter is about even with an upper surface of the second color filter and an upper surface of the third color filter.

16. The method according to claim 10, wherein the insulating layer structure further comprises:
a second trench over the second photodiode, wherein the second color filter is formed on the second trench.

17. The method according to claim 16, wherein the second color filter is thicker than the first color filter, and wherein the third color filter is thicker than the second color filter.

18. The method according to claim 10, wherein an upper surface of the first color filter is about even with an upper surface of the second color filter and an upper surface of the third color filter.

19. The method according to claim 10, wherein the first color filter is a blue color filter, the second color filter is a green color filter, and the third color filter is a red color filter.

20. The method according to claim 11, further comprising forming a microlens on each of the first color filter, the second color filter, and the third color filter.
